(19) United States
(12) Patent Application Publication
(10) Pub. No.: US 2009/0133738 A1
(43) Pub. Date: May 28, 2009

(54) Photovoltaic Roofing Elements and Roofs Using Them

(76) Inventors: Ming-Liang Shiao, Collegeville, PA (US); Gregory F. Jacobs, Oreland, PA (US); Wayne E. Shaw, Glen Mills, PA (US); Robert D. Livsey, Limerick, PA (US)

Correspondence Address: MCDONNELL BOEHNEN HULBERT & BERGHOFF LLP, 300 S. WACKER DRIVE, 32ND FLOOR, CHICAGO, IL, 60606, US

(21) Appl. No.: 12/266,481

(22) Filed: Nov. 6, 2008

Related U.S. Application Data
(60) Provisional application No. 60/985,940, filed on Nov. 6, 2007.
(60) Provisional application No. 60/985,943, filed on Nov. 6, 2007.
(60) Provisional application No. 60/986,221, filed on Nov. 7, 2007.

(51) Int. Cl. H01L 31/048; E04D 13/18

(52) U.S. Cl. 136/251; 52/173.3

(57) ABSTRACT

The present invention relates generally to photovoltaic devices. The present invention relates more particularly to photovoltaic roofing products in which a photovoltaic element is affixed to a roofing substrate. In one embodiment, the present invention provides a photovoltaic roofing element comprising a roofing substrate having a solar reflectivity of greater than 0.25, and one or more photovoltaic elements affixed to the roofing substrate. In another embodiment, the present invention provides a photovoltaic roofing element comprising a roofing substrate comprising a bituminous substrate, and a plurality of colored roofing granules disposed on the bituminous substrate, the roofing substrate having color within the color space of CIE Lab coordinates L* in the range of about 20 to about 20, a* in the range of about −5 to about 5, and b* in the range of −15 to about −5; and one or more photovoltaic elements affixed to the roofing substrate.

### CROSS-REFERENCE TO RELATED APPLICATIONS

This application claims priority under 35 U.S.C. § 119(e) to U.S. Provisional Patent Applications Ser. No. 60/985,940, filed Nov. 6, 2007; Ser. No. 60/985,943, filed Nov. 6, 2007; and Ser. No. 60/986,221, filed Nov. 7, 2007, each of which is hereby incorporated herein by reference in its entirety.

### BACKGROUND OF THE INVENTION

1. Field of the Invention

The present invention relates generally to photovoltaic devices. The present invention relates more particularly to photovoltaic roofing products in which a photovoltaic element is affixed to a roofing substrate.

2. Summary of the Related Art

The search for alternative sources of energy has been motivated by at least two factors. First, fossil fuels have become increasingly expensive due to increasing scarcity and unrest in areas rich in petroleum deposits. Second, there exists overwhelming concern about the effects of the combustion of fossil fuels on the environment due to factors such as air pollution (from NOₓ, hydrocarbons and ozone) and global warming (from CO₂). In recent years, research and development attention has focused on harvesting energy from natural environmental sources such as wind, flowing water, and the sun. Of the three, the sun appears to be the most widely useful energy source across the continental United States; most locales get enough sunshine to make solar energy feasible.

Accordingly, there are now available components that convert light energy into electrical energy. Such “photovoltaic cells” are often made from semiconductor-type materials such as doped silicon in either single crystalline, polycrystalline, or amorphous form. The use of photovoltaic cells on roofs is becoming increasingly common, especially as device performance has improved. They can be used to provide at least a significant fraction of the electrical energy needed for a building's overall function; or they can be used to power one or more particular devices, such as exterior lighting systems.

Existing photovoltaic modules do not blend well aesthetically with conventional roofing materials. Photovoltaic materials tend to have a deep blue/purple/black color, which lends them increased solar absorptivity and therefore increased efficiency. Standard asphalt composite shingles, for example, are generally grey, black, green or brown in tone. The color contrast between photovoltaic materials and standard asphalt composite shingles can be dramatic.

Moreover, photovoltaic efficiency tends to decrease as a function of temperature. The surface temperature of an exposed rooftop can climb as high as 50° C. above ambient temperatures, causing a concomitant decrease in efficiency. In fact, photovoltaic materials generate heat as a byproduct of photovoltaic power generation, further decreasing efficiency. The loss in efficiency can be as much as 0.5 percent per degree rise in temperature.

### SUMMARY OF THE INVENTION

One aspect of the present invention is a photovoltaic roofing element comprising: a roofing substrate having a solar reflectivity of greater than 0.25, and one or more photovoltaic elements affixed to the roofing substrate.

Another aspect of the invention is a photovoltaic roofing element comprising:
a roofing substrate comprising a bituminous substrate, and a plurality of colored roofing granules disposed on the bituminous substrate, the roofing substrate having color within the color space of CIE Lab coordinates L* in the range of about 20 to about 30, a* in the range of about −5 to about 5, and b* in the range of −15 to about −5; and
one or more photovoltaic elements affixed to the roofing substrate.

Another aspect of the invention is a roof comprising a plurality of photovoltaic roofing elements as described above disposed on a roof deck.

The photovoltaic roofing elements and roofs of the present invention can result in a number of advantages over prior art roofing elements and roofs. For example, the photovoltaic roofing elements according to certain embodiments of the present invention can provide lower temperature operation for photovoltaic power generation, and therefore higher photovoltaic efficiency. The photovoltaic roofing elements according to certain embodiments of the present invention can also have better resistance to bond failure between the photovoltaic element and the roofing substrate. Moreover, the photovoltaic roofing elements according to certain embodiments of the present invention can have better aesthetic matching between the photovoltaic element and the roofing substrate.

The accompanying drawings are not necessarily to scale, and sizes of various elements can be distorted for clarity.

### BRIEF DESCRIPTION OF THE DRAWINGS

FIG. 1 is a schematic cross-sectional view of a photovoltaic roofing element according to one embodiment of the invention;

FIG. 2 is a schematic exploded view of an encapsulated photovoltaic element suitable for use in the present invention;

FIG. 3 is a schematic cross-sectional view of a photovoltaic roofing element according to another embodiment of the invention;

FIGS. 4, 5, 6 and 7 are schematic cross-sectional views of examples of roofing granules suitable for use in the present invention;

FIGS. 8 and 9 are schematic top and bottom views of a photovoltaic roofing element according to one embodiment of the invention;

FIG. 10 is a schematic cross-sectional view of a photovoltaic roofing element according to another embodiment of the invention;

FIG. 11 is a schematic cross-sectional view of a photovoltaic roofing element according to another embodiment of the invention;

FIG. 12 is a top perspective view of a photovoltaic roofing element according to one embodiment of the invention; and

FIG. 13 is a three-dimensional graph depicting the color space of certain materials suitable for use in the present invention.

### DETAILED DESCRIPTION OF THE INVENTION

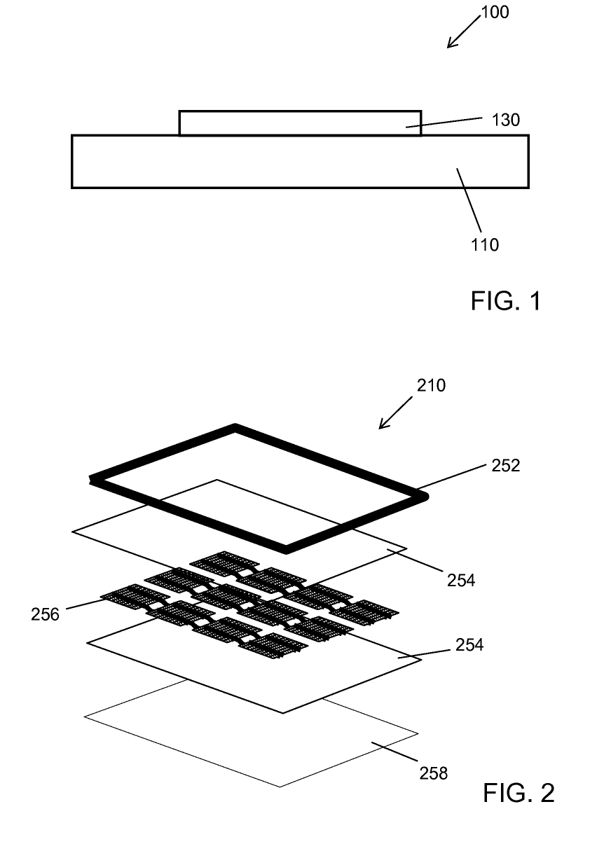

One embodiment of a photovoltaic roofing element according to the present invention is shown in schematic cross-sectional view in FIG. 1. Photovoltaic roofing element 100 and comprises a roofing substrate 110 and one or more photovoltaic elements 130 disposed on the roofing substrate 110. The roofing substrate has a solar reflectivity of greater than 0.25, as determined using ASTM C-1549 using a SSR-ER solar spectrum reflectometer. In the embodiment of FIG. 1, the photovoltaic element is disposed on the roofing substrate. However, the person of skill in the art will appreciate that the photovoltaic element can be affixed to the roofing substrate in other arrangements. For example, the photovoltaic element can be affixed to the underside of the roofing substrate, with its photovoltaically-active area in registration with a void or aperture in the substrate (e.g., a hole, or a cut out area along an edge). Accordingly, for particular embodiments of the invention in which the photovoltaic element is described as being “disposed on” a roofing substrate, the person of skill in the art will recognize that the photovoltaic element can be affixed to the roofing substrate in another arrangement.

In use, the solar reflectivity of the roofing substrate can help to reduce the amount of heat buildup in the roof by reflecting infrared radiation instead of absorbing it. The reduction of heat buildup can allow the photovoltaic element to operate at higher efficiency. The reduction of heat buildup can also reduce heat damage to the photovoltaic roofing element, and reduce heat buildup in the interior of the building on which the photovoltaic roofing elements are disposed, thereby increasing overall energy efficiency, for example by reducing the necessary air conditioning load. Moreover, because the roofing substrate undergoes lower temperature excursions while installed, the photovoltaic roofing elements of the present invention can be less prone to thermal mismatch-induced failure of the bond between the roofing substrate and the photovoltaic element and can be less subject to heat distortion. Accordingly, a wider range of attachment methods and materials are available for use in constructing the photovoltaic roofing elements of the present invention. In certain embodiments of the invention in which larger roofing substrates are used, bowing due to differential expansion between the solar-lit side (hotter) and the underside (cooler) can be reduced.

In certain embodiments of the invention, the roofing substrate has an L* value of less than 85. For example, the L* value of the roofing substrate can be less than 55, or even less than 45. As used herein L*, a* and b* are the color measurements for a given sample using the 1976 CIE color space. The strength in color space E* is defined as E*=(L*²+a*²+b*²)^{1/2}. The total color difference ΔE* between two articles is defined as ΔE*=(ΔL*²+Δa*²+Δb*²)^{1/2}, in which ΔL*, Δa* and Δb* are respectively the differences in L*, a* and b* for the two articles. L*, a* and b* values are measured using a HunterLab Model Labscan XE spectrophotometer using a 0° viewing angle, a 45° illumination angle, a 10° standard observer, and a D-65 illuminant. Lower L* values correspond to relatively darker tones. Photovoltaic elements comprising colored roofing granules are described in more detail below; the details of the embodiments described with respect to colored roofing granules can likewise be applied to the solar-reflective roofing granules in this aspect of the invention. For example, in certain embodiments of the invention, the roofing substrate has an average color falling within a color space having L* in the range of about 20 to about 30, a* in the range of about −5 to about 5, and b* in the range of −15 to about −5. In other embodiments of the invention, the roofing substrate has a ΔE*<30 compared to the top surface of the photovoltaic element. In some embodiments, the roofing substrate has a ΔE*<20 compared to the top surface of the photovoltaic element.

In certain embodiments of the invention, the photovoltaic element can be joined to the roofing substrate through a tie layer system, as described in the U.S. patent application Ser. No. 12/266,409, entitled “Photovoltaic Roofing Elements Including Tie Layer Systems, Roofs Using Them, and Methods for Making Them,” filed on even date herewith, as well as U.S. Provisional Patent Applications Ser. No. 60/985,932, filed Nov. 6, 2007; Ser. No. 60/985,935, filed Nov. 6, 2007; and Ser. No. 60/986,556, filed Nov. 8, 2007, each of, which is hereby incorporated herein by reference in its entirety. Examples of suitable tie layers, depending on the application, include oxidized asphalt, SBS-modified asphalt, APP-modified asphalt, adhesives, polypropylene/EVA blends, pressure-sensitive adhesives, and maleic anhydride-grafted EVA, polypropylene/polyethylene copolymers, butyl adhesives, pressure sensitive adhesives, or functionalized EVA. The tie layer systems can also include a layer of fibrous material, mineral particles, roofing granules, felt, or porous web partially embedded in the material of the roofing substrate.

Photovoltaic element 130 comprises one or more interconnected photovoltaic cells. The photovoltaic cells of photovoltaic element 130 can be based on any desirable photovoltaic material system, such as monocrystalline silicon; polycrystalline silicon; amorphous silicon; III-V materials such as indium gallium nitride; II-VI materials such as cadmium telluride; and more complex chalcogenides (group VI) and pnicogenides (group V) such as copper indium diselenide or CIGS. For example, one type of suitable photovoltaic cell includes an n-type silicon layer (doped with an electron donor such as phosphorus) oriented toward incident solar radiation on top of a p-type silicon layer (doped with an electron acceptor, such as boron), sandwiched between a pair of electrically-conductive electrode layers. Another type of suitable photovoltaic cell is an indium phosphide-based thermo-photovoltaic cell, which has high energy conversion efficiency in the near-infrared region of the solar spectrum. Thin film photovoltaic materials and flexible photovoltaic materials can be used in the construction of encapsulated photovoltaic elements for use in the present invention. In one embodiment of the invention, the photovoltaic element includes a monocrystalline silicon photovoltaic cell or a polycrystalline silicon photovoltaic cell.

The photovoltaic element can be an encapsulated photovoltaic element, in which photovoltaic cells are encapsulated between various layers of material. For example, encapsulated photovoltaic element can include a top layer material at its top surface, and a bottom layer material at its bottom surface. The top layer material can, for example, provide environmental protection to the underlying photovoltaic cells, and any other underlying layers. Examples of suitable materials for the top layer material include fluoropolymers, for example ETFE (e.g., NORTON® ETFE film available from Saint Gobain), PFE, FEP e.g., NORTON® FEP film available from Saint Gobain), PCTFE or PVDF. The top layer material can alternatively be, for example, a glass sheet, or a non-fluorinated polymeric material. The bottom layer material can be, for example, a fluoropolymer, for example ETFE, PFE, FEP, PVDF or PVF (“TEDLAR”). The bottom layer material can alternatively be, for example, a polymeric material (e.g., polyester such as PET, or a polyolefin such as polyethylene); or a metallic material (e.g., stainless steel or aluminum sheet).

As the person of skill in the art will appreciate, an encapsulated photovoltaic element can include other layers interspersed between the top layer material and the bottom layer material. For example, an encapsulated photovoltaic element can include structural elements (e.g., a reinforcing layer of glass fiber, microspheres, metal or polymer fibers, or a rigid film); adhesive layers (e.g., EVA to adhere other layers together); mounting structures (e.g., clips, holes, or tabs); and one or more optionally connectorized electrical cables for electrically interconnecting the photovoltaic cell(s) of the encapsulated photovoltaic element with an electrical system. An example of an encapsulated photovoltaic element suitable for use in the present invention is shown in schematic exploded view in FIG. 2. Encapsulated photovoltaic element 210 includes a top protective layer 252 (e.g., glass or a fluoropolymer film such as ETFE, PVDF, FEP, PFA or PCTFE); encapsulant layers 254 (e.g., EVA, functionalized EVA, crosslinked EVA, silicone, thermoplastic polyurethane, maleic acid-modified polyolefin, ionomer, or ethylene/(meth)acrylic acid copolymer); a layer of electrically-interconnected photovoltaic cells 256; and a backing layer 258 (e.g., PVDF, PVF, PET).

The photovoltaic element can include at least one antireflection coating, for example as the top layer material in an encapsulated photovoltaic element, or disposed between the top layer material and the photovoltaic cells.

Suitable photovoltaic elements and/or photovoltaic cells can be obtained, for example, from China Electric Equipment Group of Nanjing, China, as well as from several domestic suppliers such as Uni-Solar, Sharp, Shell Solar, BP Solar, USFC, FirstSolar, General Electric, Schott Solar, Evergreen Solar and Global Solar. Thin film-based photovoltaic cells can be especially suitable due to their durability, low heat generation, and off-axis energy collection capability. The person of skill in the art can fabricate encapsulated photovoltaic elements using techniques such as lamination or autoclave processes. Encapsulated photovoltaic elements can be made, for example, using methods disclosed in U.S. Pat. No. 5,273,608, which is hereby incorporated herein by reference.

The top surface of photovoltaic element is the surface presenting the photoelectrically-active areas of its one or more photoelectric cells. When installed, the photovoltaic roofing elements of the present invention should be oriented so that the top surface of the photovoltaic element is able to be illuminated by solar radiation.

The photovoltaic element also has an operating wavelength range. Solar radiation includes light of wavelengths spanning the near UV, the visible, and the near infrared spectra. As used herein, the term “solar radiation,” when used without further elaboration means radiation in the wavelength range of 300 nm to 2500 nm, inclusive. Different photovoltaic elements have different power generation efficiencies with respect to different parts of the solar spectrum. Amorphous doped silicon is most efficient at visible wavelengths, and polycrystalline doped silicon and monocrystalline doped silicon are most efficient at near-infrared wavelengths. As used herein, the operating wavelength range of a photovoltaic element is the wavelength range over which the relative spectral response is at least 10% of the maximal spectral response. According to certain embodiments of the invention, the operating wavelength range of the photovoltaic element falls within the range of about 300 nm to about 2000 nm. In certain embodiments of the invention, the operating wavelength range of the photovoltaic element falls within the range of about 300 nm to about 1200 nm.

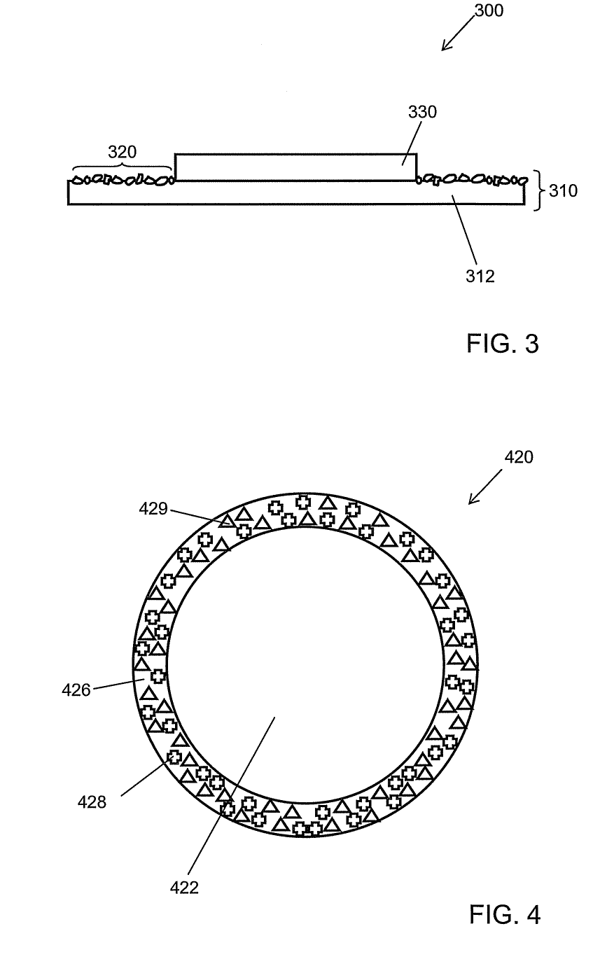

The present invention can be practiced using any of a number of types of roofing substrates. For example, in certain embodiments of the invention, the roofing substrate is a bituminous substrate having a plurality of solar-reflective roofing granules disposed thereon. For example, in the photovoltaic roofing element 300 of FIG. 3, the roofing substrate 310 includes a bituminous substrate 312 and a plurality of solar-reflective roofing granules 320 disposed thereon. The roofing substrate 310 has disposed thereon a photovoltaic element 330. The bituminous substrate can be, for example, an asphalt composite shingle substrate. The solar-reflective roofing granules are disposed on the bituminous substrate in an amount sufficient to provide the overall roofing substrate with a solar reflectivity greater than about 0.25. The solar-reflective roofing granules can operate to reflect a portion of the solar radiation (e.g., in the infrared wavelengths) and thereby decrease the buildup of heat on the roof, allowing the photovoltaic elements to operate at higher efficiency. In one embodiment of the invention, the solar-reflective roofing granules have a solar reflectivity greater than about 0.3, or even greater than about 0.4. Solar-reflective roofing granules are described, for example, in U.S. Pat. No. 7,241,500, and U.S. Patent Application Publication no. 2005/0072110, each of which is hereby incorporated herein by reference in its entirety.

In certain embodiments of the invention, the solar-reflective roofing granules comprise base particles coated with a coating composition comprising a binder and at least one infrared-reflective pigment. The binder can be, for example, a metal silicate binder or a polymeric binder suitable for outdoor exposure. The infrared-reflective pigment can comprise, for example, a solid solution including iron oxide as described in U.S. Pat. No. 6,174,360; and/or a near-IR-reflecting composite pigment as described in U.S. Pat. No. 6,521,038. Infrared-reflective “functional” pigments such as light-interference platelet pigments including titanium dioxide, light-interference platelet pigments based on metal oxide coated substrates, mirrorized silica pigments based on metal doped silica, and alumina can also be used instead of or in addition to other infrared-reflective pigments. Infrared-reflective functional pigments can enhance the solar reflectivity when incorporated in roofing granules.

In other embodiments of the invention, the solar-reflective roofing granules comprise base particles coated with a first coating composition including a binder and at least one reflective white pigment; and a second coating composition disposed about the first coating composition and comprising a binder and at least one colorant selected from the group consisting of UV-stabilized dyes and granule coloring pigments, such as those based on metal oxides, colored infrared-reflective pigments, and infrared-reflective functional pigments. In these embodiments of the invention, the first (inner) coating composition can reflect most of the solar radiation that penetrates the second (outer) coating, thereby improving the overall solar reflectivity. The reflective white pigment can be based, for example, on titanium dioxide, zinc oxide or zinc sulfide. In certain embodiments of the invention, the first coating composition comprising the reflective white pigment has a solar reflectivity of at least 0.6.

In other embodiments of the invention, the solar-reflective roofing granules comprise base particles coated with a first coating composition comprising a binder and at least one colorant selected from the group consisting of UV-stabilized dyes and granule coloring pigments, such as those based on metal oxides, colored infrared-reflective pigments, and infrared-reflective functional pigments; and a second coating composition disposed about the first coating composition and comprising a binder and at least one infrared-reflective pigment. In these embodiments of the invention, the first (inner) coating composition helps to provide a desired color (alone or in combination with the infrared-reflective pigment), and the second (outer) coating reflects infrared in order to provide solar reflectivity. The infrared-reflective can be, for example, selected from the group consisting of light-interference platelet pigments including mica, light interference platelet pigments including titanium dioxide, mirrorized silica pigments based on metal-doped silica, and alumina. Transparent IR-reflective pigments, nanoparticulate titanium dioxide, or mirrorized fillers, for example, can be used as the infrared-reflective pigment.

Binders for use in the present invention can be inorganic or organic. For example, suitable inorganic binders can include aluminosilicate materials (clay) and alkali metal silicates. Phosphate-based systems can also be used as inorganic binders, as described in U.S. Patent Application Publication no. 2008/0241516, which is hereby incorporated herein by reference in its entirety. In certain embodiments of the invention, however, the binder does not include kaolin. Suitable organic binders can include organic polymers such as acrylic polymers and copolymers. As the person of skill in the art will appreciate, the selection of a binder will depend on the nature of the pigments employed.

The solar-reflective roofing granules used in the present invention can have a higher heat reflectance than conventional roofing granules prepared only with conventional metal oxide colorants, which typically have a solar reflectivity in the range of 0.12 to 0.20. Accordingly, they can be used to make roofing substrates having solar reflectivity of at least 0.25, or even of at least about 0.3, or at least about 0.4. The solar-reflective roofing granules can be of a number of different colors selected to provide a desired overall appearance, as is conventional in asphalt shingle manufacturing. Moreover, the solar-reflective roofing granules can be used in combination with a minor amount of conventional roofing granules in order to provide the desired combination of appearance and solar reflectivity.

The solar-reflective roofing granules used in the present invention can be prepared through conventional granule coating methods, such as those disclosed in U.S. Pat. No. 2,981,636, which is hereby incorporated by reference in its entirety. Suitable base particles, for example, mineral particles with size passing #8 mesh and retaining on #70 mesh, can be coated with a blend of binder and pigment, followed by heat treatment to obtain a durable coating. The coating process can be repeated multiple times with the same coating composition to further enhance color and solar reflectivity.

In certain embodiments of the invention, the solar roofing granules are relatively dark in color. For example, in one embodiment of the invention, the solar-reflective roofing granules can have an L* less than 55, or even less than 35.

The base particles employed in the granules useful in the present invention can be chemically inert materials, such as inert mineral particles. The mineral particles, which can be produced by a series of quarrying, crushing, and screening operations, are generally intermediate between sand and gravel in size (that is, between about 8 US mesh and 70 US mesh), and can, for example, have an average particle size of from about 0.2 mm to about 3 mm, and more preferably from about 0.4 mm to about 2.4 mm. In particular, suitably sized particles of naturally occurring materials such as talc, slag, granite, silica sand, greenstone, andesite, porphyry, marble, syenite, rhyolite, diabase, greystone, quartz, slate, trap rock, basalt, and marine shells can be used, as well as recycled manufactured materials such as crushed bricks, concrete, porcelain, ceramic grog and fire clay.

In certain embodiments of the invention, the base particles comprise particles having a generally plate-like geometry. Examples of generally plate-like particles include mica and flaky slate. Roofing granules having a generally plate-like geometry can provide greater surface coverage when used to prepare bituminous roofing products, when compared with conventional “cubical” roofing granules. In certain embodiments of the invention, the granule surface coverage (i.e., for both the solar-reflective roofing granules and any conventional granules) is at least about 90%. Granule surface coverage is measured using image analysis software, namely, Image-Pro Plus from Media Cybernetics, Inc., Silver Spring, Md. 20910. The shingle surface area is recorded in a black and white image using a CCD camera fitted to a microscope. The image is then separated into an asphalt coating portion and a granule covering portion using the threshold method in gray scale. The amount of granule coverage is then calculated by the image analysis software based upon the number of pixels with gray scale above the threshold level divided by the total number of pixels in the image.

FIG. 4 is a cross-sectional schematic view of the structure of a colored infrared-reflective roofing granule 420 suitable for use in certain embodiments of the invention. In FIGS. 4-7, the granules are shown as having a circular cross-section; the person of skill in the art will appreciate that the granules can generally be substantially irregularly-shaped. The colored infrared-reflective roofing granule 420 includes a base particle 422 coated with a coating composition comprising a binder 426 and at least one colored, infrared-reflective pigment 428. In certain embodiments of the invention, the at least one colored, infrared-reflective pigment 428 is selected from the group consisting of (1) infrared-reflective pigments comprising a solid solution including iron oxide and (2) near infrared-reflecting composite pigments. The infrared-reflective pigment 428 can be present, for example, from about 1 percent by weight to about 60 percent by weight of the coating composition. In one embodiment, and as shown in FIG. 4, the coating composition of the colored infrared-reflective roofing granules 420 further comprises at least one infrared-reflective functional pigment 429 selected from the group consisting of light-interference platelet pigments including mica, light-interference platelet pigments including titanium dioxide, mirrorized silica pigments based upon metal-doped silica, and alumina. The coating composition can be present, for example an amount from about 2 percent by weight of the base particles 422 to about 20 percent by weight of the base particles 422. When alumina is included in the coating composition as an infrared-reflective functional pigment 429, the particle size of the alumina is preferably less than 425 μm. Thus, in the embodiment of FIG. 4, the infrared reflectance of the roofing granules can be attributed to the colored, infrared-reflective pigment and the optional infrared-reflective functional pigment, while the color of the granules is substantially attributable to the colored, infrared-reflective pigment.

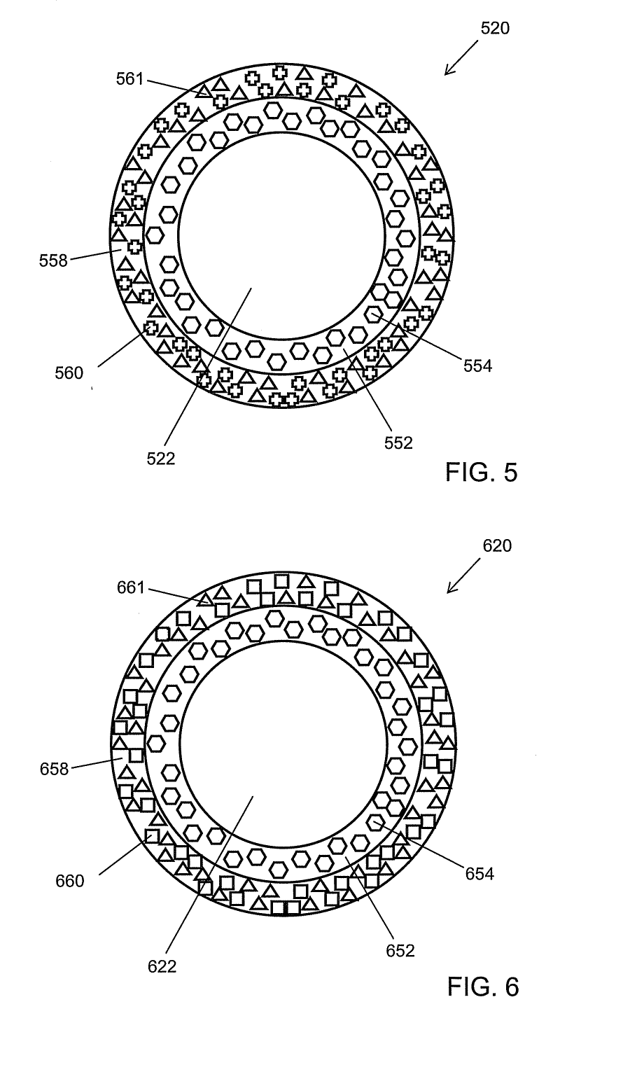

FIG. 5 is a schematic illustration of the structure of another colored infrared-reflective roofing granule 520 according to a presently preferred second embodiment of the present invention. In this embodiment, roofing granule 520 includes a base particle 522, a first coating composition comprising a binder 552 and at least one reflective white pigment 554, and a second coating composition disposed around the first coating composition, the second coating composition comprising a binder 558 and colored, infrared-reflective pigment 560, as well as an optional infrared-reflective functional pigment 561, as in the coating composition described above with reference to FIG. 4. The at least one reflective white pigment can be, for example, selected from the group consisting of titanium dioxide, zinc oxide and zinc sulfide. In certain embodiments of the invention, the at least one reflective white pigment 554 is present in an amount in the range of from about 5 percent by weight to about 60 percent by weight of the first coating composition. The binder 552 used in conjunction with the reflective white pigment preferably comprises an aluminosilicate material and an alkali metal silicate, and the aluminosilicate material is preferably clay, although an organic material can optionally be employed. Thus, in the embodiment of FIG. 5, a first coating composition including a white, solar-reflective pigment such can cover the dark colored, low infrared-reflective mineral surface. The second coating composition can create deeper tones of colors while generating a surface with high reflectance for solar heat. In this embodiment, the infrared reflectance of the colored roofing granules can be attributed to the reflective white pigment in the first (inner) coating composition, as well as to the colored, infrared-reflective pigment and the optional infrared-reflective functional pigment in the second (outer) coating composition, while the color of the granules is substantially attributable to the colored, infrared-reflective pigment in the second coating composition.

FIG. 6 is a schematic illustration of the structure of a colored infrared-reflective roofing granule 620 according to another embodiment of the invention. Colored infrared-reflective roofing granule 620 comprises a base particle 622, a first coating composition comprising a binder 652 and at least one reflective white pigment 654, and a second coating composition disposed about the first coating composition, the second coating composition comprising a binder 658, and at least one colorant 660 selected from the group consisting of UV-stabilized dyes and granule coloring pigments. In certain embodiments of the invention, the second coating composition is substantially transparent to infrared radiation (e.g., at least 50%, preferably at least 75% transmittance). The thickness of the second coating composition and the identity and amount of the at least one colorant 660 can be selected to provide both high infrared transparency and the desired color tone for the roofing granule 620. In certain embodiments, and as shown in FIG. 6, the second coating composition can optionally further comprise at least one infrared-reflective functional pigment 661 selected from the group consisting of light-interference platelet pigments including mica, light-interference platelet pigments including titanium dioxide, mirrorized silica pigments based upon metal-doped silica, and alumina. Thus, in embodiments according to FIG. 6, the infrared reflectance of the colored roofing granules can be attributed to the reflective white pigment in the first coating composition, and any optional infrared-reflective functional pigment in the second coating composition, while the color of the granules can be substantially attributed to the colorant in the second coating composition.

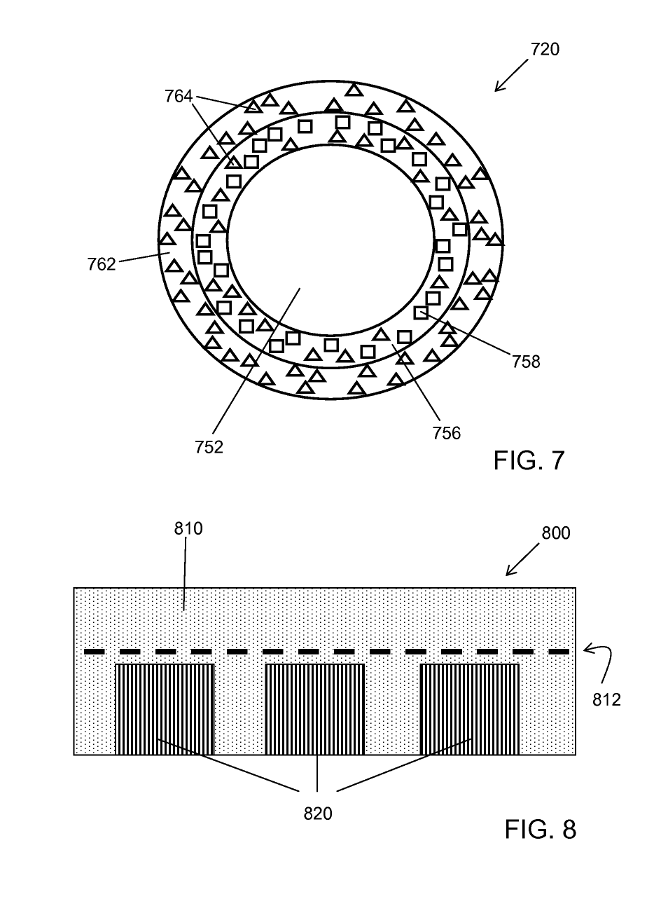

FIG. 7 is a schematic illustration of the structure of a colored infrared-reflective roofing granule 720 according to another embodiment of the present invention. In this embodiment, the colored infrared-reflective roofing granule 720 comprises base particles 752 coated with a first coating composition comprising a binder 756 and at least one colorant 758 selected from the group consisting of UV-stabilized dyes and granule coloring pigments, and a second coating composition disposed about the first coating composition, the second coating composition comprising a binder 762 and at least one infrared-reflective functional pigment 764 selected from the group consisting of light-interference platelet pigments including mica, light-interference platelet pigments including titanium dioxide, mirrorized silica pigments based upon metal-doped silica, and alumina. Optionally, and as shown in FIG. 7, the first coating composition also comprises at least one infrared-reflective functional pigment 764. In certain embodiments of the invention, the second coating composition is substantially transparent to infrared radiation (e.g., at least 50%, preferably at least 75% transmittance). The thickness of the second coating composition and the identity and amount of the at least one colorant 758 can be selected to provide both high infrared transparency and the desired color tone for the roofing granule 720. In the embodiment of FIG. 7, the infrared reflectance of the colored roofing granules can be attributed to the infrared-reflective functional pigment in the second coating composition as well as any optional infrared-reflective functional pigment in the first coating composition, while the color of the granules is substantially attributable to the colorant in the first coating composition.

In another embodiment of the invention, the solar-reflective roofing granules comprise colored roofing granules coated with a coating composition comprising a binder and at least one infrared-reflective functional pigment selected from the group consisting of light-interference platelet pigments including mica, light-interference platelet pigments including titanium dioxide, mirrorized silica pigments based upon metal-doped silica, and alumina. The solar reflectivity can be increased, while substantially maintaining the color of the roofing granules (e.g., ΔE* no more than 10).

When alumina is employed as the at least one infrared-reflective pigment, the alumina (aluminum oxide) preferably has a particle size less than #40 mesh (425 μm), for example in the range of 0.1 μm to 5 μm. In certain embodiments of the invention, the alumina is greater than 90 percent by weight Al₂O₃.

When a coating composition includes an infrared-reflective functional pigment, it can be present at a level in the range of, for example, about 1 percent by weight to about 60 percent by weight of the coating composition. Preferably, the infrared-reflective coating can be provided in a thickness effective to render the coating opaque to infrared radiation, such as a coating thickness of at least about 100 μm. However, advantageous properties can be realized with significantly lower coating thicknesses, such as at a coating thickness of from about 2 μm to about 25 μm, including at a coating thickness of about 5 μm.

In certain embodiments of the invention, one or more coating compositions include a colored, infrared-reflective pigment, for example comprising a solid solution including iron oxide, such as disclosed in U.S. Pat. No. 6,174,360, which is hereby incorporated herein by reference in its entirety; or a near infrared-reflecting composite pigment such as disclosed in U.S. Pat. No. 6,521,038, which is hereby incorporated herein by reference in its entirety. Composite pigments are composed of a near-infrared non-absorbing colorant of a chromatic or black color and a white pigment coated with the near infrared-absorbing colorant. Near-infrared non-absorbing colorants that can be used in the present invention include organic pigments such as organic pigments including azo, anthraquinone, phthalocyanine, perinone/perylene, indigo/thioindigo, dioxazine, quinacridone, isoindolinone, isoindoline, diketopyrrolopyrrole, azomethine, and azomethine-azo functional groups. Preferred black organic pigments include organic pigments having azo, azomethine, and perylene functional groups. Colored, infrared-reflective pigments can be present, for example, at a level in the range of about 0.5 percent by weight to about 40 percent by weight of the base coating composition. Preferably, such a coating composition forms a layer having sufficient thickness to provide good hiding and opacity, such as a thickness of from about 5 μm to about 50 μm.

In certain embodiments of the invention, a coating composition includes at least one coloring material selected from the group consisting of coloring pigments and UV-stabilized dyes. Suitable coloring pigments include transition metal oxides.

A binder used to form a coating composition including an infrared-reflective pigment is preferably formed from a mixture of an alkali metal silicate, such as aqueous sodium silicate, and heat reactive aluminosilicate material, such as clay. The proportion of alkali metal silicate to heat-reactive aluminosilicate material is preferably from about 3:1 to about 1:3 parts by weight alkali metal silicate to parts by weight heat-reactive aluminosilicate material, more preferably about 2:1 to about 0.8:1 parts by weight alkali metal silicate to parts by weight heat-reactive aluminosilicate material. Alternatively, the base particles can be first mixed with the heat reactive aluminosilicate to coat the base particles, and the alkali metal silicate can be subsequently added with mixing. The binder used in other coating compositions can similarly be formed from a mixture of an alkali metal silicate, such as aqueous sodium silicate, and heat reactive aluminosilicate material, such as clay.

When the infrared-reflective granules are fired at an elevated temperature, such as at least about 200° C., the clay reacts with and neutralizes the alkali metal silicate, thereby insolubilizing the binder. The binder resulting from this clay-silicate process, believed to be a sodium aluminum silicate, is porous, such as disclosed in U.S. Pat. No. 2,379,358, which is hereby incorporated herein by reference in its entirety. Alternatively, the porosity of the insolubilized binder can be decreased by including an oxygen-containing boron compound such as borax in the binder mixture, and firing the granules at a lower temperature, for example, in the range of 250-400° C., such as disclosed in U.S. Pat. No. 3,255,031, which is hereby incorporated herein by reference in its entirety.

Examples of clays that can be employed in the process of the present invention include kaolin, other aluminosilicate clays, Dover clay, and bentonite clay. In certain embodiments of the invention, kaolin is not used in the manufacture of the granules, as it can greatly reduce the color strength of certain pigments.

The inorganic binder employed in the present invention can include an alkali metal silicate such as an aqueous sodium silicate solution, for example, an aqueous sodium silicate solution having a total solids content of from about 38 percent by weight to about 42 percent by weight, and having a ratio of Na₂O to SiO₂ of from about 1:2 to about 1:3.25. In other embodiments, the inorganic binder is phosphate-based, as described in U.S. Patent Application Publication no. 2008/0241516.

Organic binders can also be employed in granules used in the present invention. The use of suitable organic binders, when cured, can also provide superior granule surface with enhanced granule adhesion to the asphalt substrate and with better staining resistance to asphaltic materials. Roofing granules colored by inorganic binders often require additional surface treatments to impart certain water repellency for granule adhesion and staining resistance. U.S. Pat. No. 5,240,760 discloses examples of polysiloxane-treated roofing granules that provide enhanced water repellency and staining resistance. With the organic binders, the additional surface treatments may be eliminated. Also, certain organic binders, particularly those water-based systems, can be cured by drying at much lower temperatures as compared to the inorganic binders such as metal-silicates, which often require curing at temperatures greater than about 500° C. or by using a separate pickling process to render the coating durable.

Examples of organic binders that can be employed in the process of the present invention include acrylic polymers, alkyd and polyesters, amino resins, epoxy resins, phenolics, polyamides, polyurethanes, silicone resins, vinyl resins, polyols, cycloaliphatic epoxides, polysulfides, phenoxy, fluoropolymer resins. Examples of UV-curable organic binders that can be employed in the process of the present invention include UV-curable acrylates and UV-curable cycloaliphatic epoxides.

An organic material can be employed as a binder for the coating composition used in the granules of the present invention. Preferably, a hard, transparent organic material is employed. Especially preferred are UV-resistant polymeric materials, such as poly(meth)acrylate materials, including poly methyl methacrylate, copolymers of methyl methacrylate and alkyl acrylates such as ethyl acrylate and butyl acrylate, and copolymers of acrylate and methacrylate monomers with other monomers, such as styrene. Preferably, the monomer composition of the copolymer is selected to provide a hard, durable coating. If desired, the monomer mixture can include functional monomers to provide desirable properties, such as crosslinkability to the copolymers. The organic material can be dispersed or dissolved in a suitable solvent, such as coatings solvents well known in the coatings arts, and the resulting solution used to coat the granules using conventional coatings techniques. Alternatively, water-borne emulsified organic materials, such as acrylate emulsion polymers, can be employed to coat the granules, and the water subsequently removed to allow the emulsified organic materials of the coating composition to coalesce.

Examples of near IR-reflective pigments available from the Shepherd Color Company, Cincinnati, Ohio, include Arctic Black 10C909 (chromium green-black), Black 411 (chromium iron oxide), Brown 12 (zinc iron chromite), Brown 8 (iron titanium brown spinel), and Yellow 193 (chrome antimony titanium).

Light-interference platelet pigments are known to give rise to various optical effects when incorporated in coatings, including opalescence or “pearlescence.” Surprisingly, light-interference platelet pigments have been found to provide or enhance infrared-reflectance of roofing granules coated with compositions including such pigments.

Examples of light-interference platelet pigments that can be employed in the granules of the present invention include pigments available from Wenzhou Pearlescent Pigments Co., Ltd., No. 9 Small East District, Wenzhou Economical and Technical Development Zone, Peoples Republic of China, such as Taizhu TZ5013 (mica, rutile titanium dioxide and iron oxide, golden color), TZ5012 (mica, rutile titanium dioxide and iron oxide, golden color), TZ4013 (mica and iron oxide, wine red color), TZ4012 (mica and iron oxide, red brown color), TZ4011 (mica and iron oxide, bronze color), TZ2015 (mica and rutile titanium dioxide, interference green color), TZ2014 (mica and rutile titanium dioxide, interference blue color), TZ2013 (mica and rutile titanium dioxide, interference violet color), TZ2012 (mica and rutile titanium dioxide, interference red color), TZ2011 (mica and rutile titanium dioxide, interference golden color), TZ1222 (mica and rutile titanium dioxide, silver white color), TZ1004 (mica and anatase titanium dioxide, silver white color), TZ4001/600 (mica and iron oxide, bronze appearance), TZ5003/600 (mica, titanium oxide and iron oxide, gold appearance), TZ1001/80 (mica and titanium dioxide, off-white appearance), TZ2001/600 (mica, titanium dioxide, tin oxide, off-white/gold appearance), TZ2004/600 (mica, titanium dioxide, tin oxide, off-white/blue appearance), TZ2005/600 (mica, titanium dioxide, tin oxide, off-white/green appearance), and TZ4002/600 (mica and iron oxide, bronze appearance).

Examples of light-interference platelet pigments that can be employed in the granules of the present invention also include pigments available from Merck KGaA, Darmstadt, Germany, such as Iriodin® pearlescent pigment based on mica covered with a thin layer of titanium dioxide and/or iron oxide; Xirallic™ high chroma crystal effect pigment based upon Al₂O₃ platelets coated with metal oxides, including Xirallic T 60-10 WNT crystal silver, Xirallic™ T 60-20 WNT sunbeam gold, and Xirallic™ F 60-50 WNT fireside copper; Color Stream™ multi color effect pigments based on SiO₂ platelets coated with metal oxides, including Color Stream F 20-00 WNT autumn mystery and Color Stream F 20-07 WNT viola fantasy; and ultra interference pigments based on TiO₂ and mica.

Examples of mirrorized silica pigments that can be employed in the process of the present invention include pigments such as Chrom Brite™ CB4500, available from Bead Brite, 400 Oser Ave, Suite 600, Hauppauge, N.Y. 11788.

The use of pigments for reducing solar heat absorption in roofing applications is disclosed in co-pending U.S. Patent Application Publication Nos. 2005/0072110 and U.S. Pat. No. 7,241,500, each of which are hereby incorporated herein by reference in its entirety.

As described above, the solar-reflective roofing granules used in the present invention can include conventional coatings pigments. Examples of coatings pigments that can be used include those provided by the Color Division of Ferro Corporation, 4150 East 56th St., Cleveland, Ohio 44101, and produced using high temperature calcinations, including PC-9415 Yellow, PC-9416 Yellow, PC-9158 Autumn Gold, PC-9189 Bright Golden Yellow, V-9186 Iron-Free Chestnut Brown, V-780 Black, V0797 IR Black, V-9248 Blue, PC-9250 Bright Blue, PC-5686 Turquoise, V-13810 Red, V-12600 Camouflage Green, V12560 IR Green, V-778 IR Black, and V-799 Black. Further examples of coatings pigments that can be used include white titanium dioxide pigments provided by Du Pont de Nemours, P.O. Box 8070, Wilmington, Del. 19880.

Pigments with high near IR transparency are preferred for use in coatings applied over white, reflective base coats. Such pigments include pearlescent pigments, light-interference platelet pigments, ultramarine blue, ultramarine purple, cobalt chromite blue, cobalt aluminum blue, chrome titanate, nickel titanate, cadmium sulfide yellow, cadmium sulfoselenide orange, and organic pigments such as phthalo blue, phthalo green, quinacridone red, diarylide yellow, and dioxazine purple. Conversely, color pigments with significant infrared absorbency and/or low infrared transparency are preferably avoided when preparing coatings for use over white, reflective base coats. Examples of pigments providing high infrared absorbency and/or low infrared transparency include carbon black, iron oxide black, copper chromite black, iron oxide brown natural, and Prussian blue. In certain embodiments of the invention, the granules are substantially non-transparent to ultraviolet radiation.

The post-functionalization processes described in U.S. Patent Application Publication no. 2008/0261007 can also be used in making roofing granules for use in the present invention.

The solar reflectivity properties of the solar heat-reflective roofing granules useful in the present invention are determined by a number of factors, including the type and concentration of the solar heat-reflective pigment(s) used in the solar heat-reflective coating composition, whether a base coating is employed, and if so, the type and concentration of the reflective white pigment employed in the base coating, the nature of the binder(s) used in for the solar heat-reflective coating and the base coating, the number of coats of solar heat-reflective coating employed, the thickness of the solar heat-reflective coating layer and the base coating layer, and the size and shape of the base particles. In certain embodiments of the invention, the solar-reflective roofing granules have L* in the range of about 20 to about 30, a* in the range of about −5 to about 5, and b* in the range of −15 to about −5; such granules can provide increased color matching with photovoltaic materials.

Infrared-reflective coating compositions useful in this aspect of the invention can also include supplementary pigments to space infrared-reflecting pigments, to reduce absorption by multiple-reflection. Examples of such “spacing” pigments include amorphous silicic acid having a high surface area and produced by flame hydrolysis or precipitation, such as Aerosil TT600 supplied by Degussa, as disclosed in U.S. Pat. No. 5,962,143, incorporated herein by reference.

The solar-reflective roofing granules described above can be used (alone or in combination with conventional roofing granules) to provide a granule-coated bituminous substrate having L* less than 85, and more preferably less than 55, and solar reflectivity greater than 0.25. Preferably, granule-coated bituminous substrates according to the present invention comprise colored, infrared-reflective granules according to the present invention, and optionally, conventional colored roofing granules. Conventional colored roofing granules and infrared-reflective roofing granules can be blended in combinations to generate desirable colors. The blend of granules is then directly applied on to hot asphalt coating to form the shingle. Examples of granule deposition apparati that can be employed to manufacture asphalt shingles according to the present invention are provided, for example, in U.S. Pat. Nos. 4,583,486, 5,795,389, and 6,610,147, and U.S. Patent Application Publication U.S. 2002/0092596, each of which is hereby incorporated herein by reference in its entirety.

In one embodiment of the invention, granule-coated area has an appearance with a color similar to that of the top surface of the photovoltaic roofing element (e.g., ΔE*<30). In one embodiment of the invention, the granule-coated area falls within a color space having L* in the range of about 20 to about 30, a* in the range of about −5 to about 5, and b* in the range of −15 to about −5.

The bituminous substrates can be manufactured and coated with the solar-reflective roofing granules using conventional roofing production processes. Typically, bituminous roofing products are sheet goods that include a non-woven base or scrim formed of a fibrous material, such as a glass fiber scrim. The base is coated with one or more layers of a bituminous material such as asphalt to provide water and weather resistance to the roofing product. One side of the roofing product is typically coated with mineral granules to provide durability, reflect heat and solar radiation, and to protect the bituminous binder from environmental degradation. The solar-reflective roofing granules can be mixed with conventional roofing granules, and the granule mixture can be embedded in the surface of such bituminous roofing products using conventional methods. Alternatively, the solar-reflective roofing granules can be substituted for conventional roofing granules in manufacture of bituminous roofing products to provide those roofing products with solar reflectance.

Bituminous roofing products are typically manufactured in continuous processes in which a continuous substrate sheet of a fibrous material such as a continuous felt sheet or glass fiber mat is immersed in a bath of hot, fluid bituminous coating material so that the bituminous material saturates the substrate sheet and coats at least one side of the substrate. The reverse side of the substrate sheet can be coated with an anti-stick material such as a suitable mineral powder or a fine sand. Roofing granules are then distributed over selected portions of the top of the sheet, and the bituminous material serves as an adhesive to bind the roofing granules to the sheet when the bituminous material has cooled. The area(s) where the photovoltaic elements are to be located can be left substantially free of granules, for example by masking the surface with one or more templates, or using a properly-designed granule drop cycle (see, e.g., U.S. Patent Application Publication no. 2006/0260731 A1, which is hereby incorporated herein by reference in its entirety). The sheet can then be cut into conventional shingle sizes and shapes (such as one foot by three feet rectangles), slots can be cut in the shingles to provide a plurality of “tabs” for ease of installation and aesthetics, additional bituminous adhesive can be applied in strategic locations and covered with release paper to provide for securing successive courses of shingles during roof installation, and the finished shingles can be packaged. More complex methods of shingle construction can also be employed, such as building up multiple layers of sheet in selected portions of the shingle to provide an enhanced visual appearance, or to simulate other types of roofing products. Alternatively, the sheet can be formed into membranes or roll goods for commercial or industrial roofing applications.

The bituminous material used in manufacturing roofing products according to the present invention can be derived from a petroleum-processing by-product such as pitch, “straight-run” bitumen, or “blown” bitumen. The bituminous material can be modified with extender materials such as oils, petroleum extracts, and/or petroleum residues. The bituminous material can include various modifying ingredients such as polymeric materials, such as SBS (styrene-butadiene-styrene) block copolymers, resins, flame-retardant materials, oils, stabilizing materials, anti-static compounds, and the like. Preferably, the total amount by weight of such modifying ingredients is not more than about 15 percent of the total weight of the bituminous material. The bituminous material can also include amorphous polyolefins, up to about 25 percent by weight. Examples of suitable amorphous polyolefins include atactic polypropylene, ethylene-propylene rubber, etc. Preferably, the amorphous polyolefins employed have a softening point of from about 130° C. to about 160° C. The bituminous composition can also include a suitable filler, such as calcium carbonate, talc, carbon black, stone dust, or fly ash, preferably in an amount from about 10 percent to 70 percent by weight of the bituminous composite material.

The photovoltaic element(s) can be affixed to the granule-coated bituminous substrate in a number of manners. For example, when the photovoltaic element(s) are affixed to an area of the substrate that is not coated by the solar-reflective roofing granules, it can adhere directly to the softened bituminous material, or a suitable tie layer system can be used. When the photovoltaic element(s) are affixed to a granule-coated area of the substrate, a suitable tie layer system can be used. Examples of tie layer systems useful with bituminous substrates include oxidized asphalt, SBS-modified asphalt, APP-modified asphalt, adhesives, polypropylene/EVA blends, pressure sensitive adhesives, maleic anhydride-grafted EVA, polypropylene/polyethylene copolymers, butyl adhesives, and functionalized EVA. The tie layer system can also include a fibrous layer that embeds into and mechanically interlocks with the softened bituminous material. The electrical connector(s) of the photovoltaic element(s) can be disposed at the top or the bottom of the headlap area of the roofing substrate, where it will be covered by other shingles and thereby protected from the elements. Any internal wiring (e.g., interconnection) between the photovoltaic elements can be located in the back of the shingle to conceal its appearance and for shielding from foot traffic.

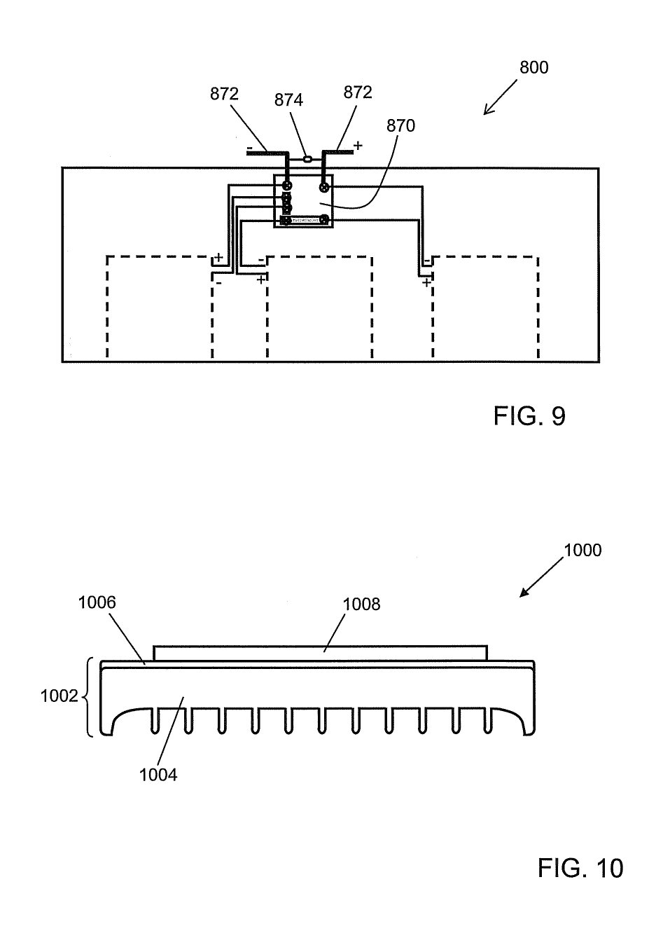

FIG. 8 is a top view of a photovoltaic roofing element according to another embodiment of the invention. Photovoltaic roofing element 800 includes a solar-reflective roofing granule-coated asphalt composite shingle 810 (which includes sealant 812 as is conventional) and three photovoltaic elements 820. The photovoltaic elements are disposed between the “dragon's teeth” tabs of the shingle in the embodiment of FIG. 8, but they could alternatively or additionally be disposed on top of the dragon's teeth. FIG. 9 shows a back view of the photovoltaic roofing element 800 of FIG. 8, in which the individual photovoltaic elements are wired together through junction box 870, and can be electrically interconnected to a larger photovoltaic system through optionally connectorized leads 872. The photovoltaic roofing element 800 also includes a bypass diode 874. Connectors useful for the electrical leads 872 are available, for example, from Tyco under the tradename Solarlok®, or from Multi-Connector under the tradename Solar Line.

Granule color measurements can be made using the Roofing Granules Color Measurement Procedure from the Asphalt Roofing Manufacturers Association (ARMA) Granule Test Procedures Manual, ARMA Form No. 441-REG-96.

In another embodiment of the invention, the roofing substrate comprises a bulk material and a solar-reflective coating disposed thereon. FIG. 10 is a cross-sectional schematic view of a photovoltaic roofing element according to this embodiment of the invention. Photovoltaic roofing element 1000 comprises a roofing substrate 1002, which includes bulk material 1004 (in this example, a polymeric roofing tile), with a solar-reflective coating 1006 disposed thereon. Photovoltaic roofing element 1000 also comprises a photovoltaic element 1008 disposed on roofing substrate 1002.

The bulk material can be virtually any roofing material. The bulk material can be, for example, a polymer. For example, the bulk material can be a polymeric roofing tile or a polymeric roofing panel. Photovoltaic roofing elements based on polymeric slates are described, for example, in U.S. patent application Ser. No. 12/146,986, which is hereby incorporated by reference in its entirety. Suitable polymers include, for example, polyolefin, polyethylene, polypropylene, ABS, PVC, polycarbonates, nylons, EPDM, fluoropolymers, silicone, rubbers, thermoplastic elastomers, polyesters, PBT, poly(meth)acrylates, and can be filled or unfilled. In other embodiments of the invention, the bulk material is metal, rubber, ceramic or fiber cement. The bulk material can also be a bituminous material, optionally coated with roofing granules, or a composite or cementitious material.

The solar-reflective coating can, for example, include the arrangements of pigments and colorants described above with respect to solar-reflective roofing granules. As the skilled artisan will appreciate, it may be necessary to use different binders in order to provide compatibility with the bulk material. For example, when the bulk material is a polymer, the binder(s) can be polymeric. The pigment/colorant systems described above can also be extruded into transparent polymeric films for lamination onto the roofing substrate.

In one embodiment of the invention, the solar-reflective coating comprises a first layer having a reflectivity of at least 0.25 for near-IR radiation (i.e., 700-2500 cm⁻¹); and a second layer disposed on the first layer, the second layer reflecting colored light but being substantially transparent to near-IR radiation (e.g., at least 85% overall energy transmittance). Such materials are described, for example, in U.S. patent application Ser. No. 11/588,577, which is hereby incorporated herein by reference in its entirety. The layers can be polymer layers, and can be co-extruded. The first layer can comprise a first polymer and can be substantially near-IR reflective. The first layer can, for example, include a white reflective pigment such as titanium dioxide, zinc oxide or zinc sulfide. The second layer can comprise a second polymer and be substantially near-IR transmissive. The second layer can have, for example, a thickness of from about 0.5 mil to about 10 mil.

The first layer can have a first coloration, and the second layer can have a second coloration different from the first coloration. In some embodiments of the invention, the second coloration substantially obscures the first coloration. The second layer can include, for example, the infrared-reflecting pigments described above. In some embodiments of the invention, the second layer includes one or more additional or alternative pigments such as pearlescent pigments, light-interference platelet pigments, ultramarine blue, ultramarine purple, cobalt chromite blue, cobalt aluminum blue, chrome titanate, nickel titanate, cadmium sulfide yellow, cadmium sulfide yellow, cadmium sulfoselenide orange, and organic pigments such as perylene black, phthalo blue, phthalo green, quinacridone red, diarylide yellow, azo red, and dioxazine purple. Additional pigments may comprise iron oxide pigments, titanium oxide pigments, composite oxide system pigments, titanium oxide-coated mica pigments, iron oxide-coated mica pigments, scaly aluminum pigments, zinc oxide pigments, copper phthalocyanine pigment, dissimilar metal (nickel, cobalt, iron, or the like) phthalocyanine pigment, non-metallic phthalocyanine pigment, chlorinated phthalocyanine pigment, chlorinated-brominated phthalocyanine pigment, brominated phthalocyanine pigment, anthraquinone, quinacridone system pigment, diketo-pyrrolipyrrole system pigment, perylene system pigment, monoazo system pigment, diazo system pigment, condensed azo system pigment, metal complex system pigment, quinophthalone system pigment, Indanthrene Blue pigment, dioxadene violet pigment, anthraquinone pigment, metal complex pigment, benzimidazolone system pigment, and the like.

The second layer, in addition to being formulated for a high degree of near-IR transparency, can comprise a material that provides superior weathering properties, e.g., clear acrylic polymers, polyolefins such as polypropylene and polyethylene, AES or ASA polymers, or fluorinated polymers. Further, in addition to pigments, the second layer may also comprise additives that provide enhanced UV protection. Additional additives may comprise antioxidants, dispersants, lubricants, and biocides/algaecides. Additionally, depending on the polymer used for the second layer formulation, heat stabilizers or hindered amine light stabilizers (HALS) may also be added. In one embodiment, where the second layer comprises ASA, a light stabilizer such as Cyasorb UV 531 (2-Hydroxy-4-n-Octoxybenzophenone light stabilizer) may be added.

Examples of suitable materials for the second layer include PVDF, PVC, ABS, PP, ASA, AES, PMMA, ASA/PVC alloy, and polycarbonate, including combinations thereof. In one preferred embodiment, the second layer comprises a mixture of ethyl acrylate (<0.1%); methyl methacrylate (<0.5%) and acrylic styrene copolymer (>99%) a commercial example of which is sold under the trade name Solarkote®).

The thickness of the second layer preferably should be as thin as possible to ensure transparency to near-IR radiation, thereby minimizing the possibility of heat buildup in the second layer itself. However, since an important function of the second layer is to provide a desired pigmentation (e.g., a dark coloration), the thickness should be sufficient to impart the desired color while hiding the underlying coloration of the first layer and the underlying roofing substrate. In some cases, it may be preferable to allow the coloration of the first layer and/or the roofing substrate to contribute to the overall color of the structured member in combination with the second layer.

Where clear acrylic polymers are used for the second layer, the thickness of the second layer can be, for example, less than about 10 mil. Where the second layer comprises an ASA polymer, the thickness can be, for example, less than about 5 mil. These thicknesses will ensure a suitable transparency of the second layer to near-IR radiation to minimize heat buildup in the second layer. It will be appreciated, however, that a thicker cap layer will enhance long-term UV protection of the first layer and the roofing substrate. Thus, in one embodiment the second layer may be thicker than about 4 mils.

Other reduced temperature color technologies can also be used, such as those developed in the “Cool Colors” program led by the Lawrence Berkeley National Lab, Berkeley, Calif. The “Cool Colors” program has developed colors that can provide reduced solar absorption in the near infrared spectrum. See, e.g., R. Levinson et al., “Solar Spectral Properties of Pigments, . . . or How to Design a Cool Nonwhite Coating,” available at http://coolcolors.lbl.gov/assets/docs/OtherTalks/HowToDesignACoolNonwhiteCoating.pdf, which is hereby incorporated herein by reference in its entirety. Also available are solar control films that are based on metals/metal oxide layers or dielectric layers formed through vacuum deposition. Such films are often used on architectural glass, but can be adapted for use on other substrates.

In certain embodiments of the invention, the roofing substrate can have solar-reflective properties over its entire area. In other embodiments of the invention, the roofing substrate has solar-reflective properties over only part of its area. For example, area that are not exposed when installed need not have solar-reflective properties. Similarly, the area(s) of the roofing substrate upon which the photovoltaic element(s) are disposed need not have solar reflective properties. For example, in the embodiment of FIG. 3, solar-reflective roofing granules do not underlie the photovoltaic element. Of course, in other embodiments of the invention, the area(s) of the roofing substrate upon which the photovoltaic element(s) are disposed have solar-reflective properties. For example, in the embodiment of FIG. 10, the solar-reflective coating does underlie the photovoltaic element.

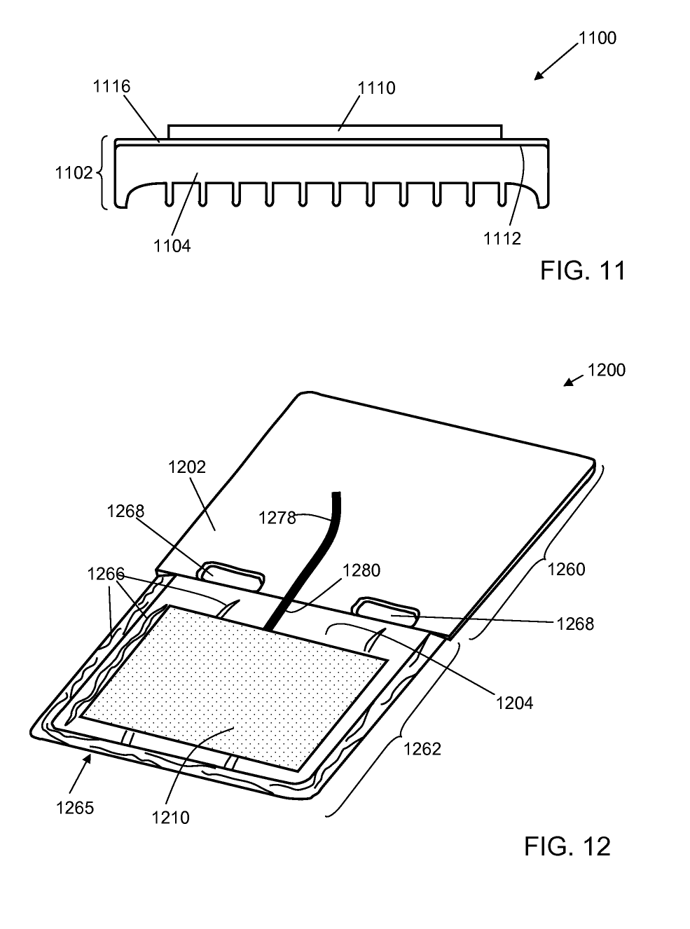

In another embodiment of the invention, the roofing substrate comprises a bulk material having a substantially infrared-reflective top surface, and a colored coating disposed thereon. FIG. 11 is a cross-sectional schematic view of a photovoltaic roofing element according to this embodiment of the invention. Photovoltaic roofing element 1100 comprises a roofing substrate 1102, which includes bulk material 1104 (in this example, a polymeric roofing panel) having a top surface 1112, with a colored coating 1116 disposed thereon. Photovoltaic roofing element 1100 also comprises a photovoltaic element 1110 disposed on roofing substrate 1102. Top surface 1112 is substantially infrared reflective. For example, it can include a white infrared reflective pigment as described above. The pigment can be filled throughout the entire bulk material, or only in a top layer of the bulk material. Such materials can be made, for example, by coextrusion. As described above, the colored coating can provide the visible color to the roofing substrate.

In one embodiment of the invention, the solar reflective coating comprises a first layer having a reflectivity of at least 0.25 for near-IR radiation (i.e., 700-2500 cm⁻¹); and a second layer disposed on the first layer, the second layer reflecting colored light (i.e., visible light), but being substantially transparent to near-IR radiation.

FIG. 12 shows a particular photovoltaic roofing element according to this aspect of the invention. Photovoltaic roofing element 1200 includes a polymeric carrier tile 1202 having a headlap portion 1260 and a butt portion 1262. The butt portion 1262 has a solar reflectivity of at least 0.25. The photovoltaic element 1210 is affixed to polymeric carrier tile 1202 in its butt portion 1262. In certain embodiments of the invention, and as shown in FIG. 12, the butt portion 1262 of the polymeric carrier tile 1202 has features 1266 molded into its surface, in order to provide a desired appearance to the polymeric carrier tile. In the embodiment shown in FIG. 12, the polymeric carrier tile 1202 has a pair of recessed nailing areas 1268 formed in its headlap portion 1260, for example as described in International Patent Application Publication no. WO 08/052,029, which is hereby incorporated herein by reference in its entirety. In certain embodiments of the invention, and as shown in FIG. 12, the photovoltaic element 1210 has coupled to it at least one electrical lead 1278. The electrical lead can be disposed in a channel 1280 formed in the top surface 1204 of the polymeric carrier tile 1202. The U-shaped periphery along the right and left sides and lower edge of the butt portion 1262 slopes downwardly from its top surface to its bottom surface, as shown at 1265. Examples of these photovoltaic roofing elements are described in more detail in U.S. patent application Ser. No. 12/146,986, which is hereby incorporated herein by reference in its entirety.

The photovoltaic roofing elements can be constructed with roofing substrates having venting structures, for example as described in U.S. Provisional Patent Applications No. 60/986,425 and in U.S. Pat. Nos. 6,061,978; 6,883,290; and 7,187,295, each of which is incorporated herein by reference in its entirety. Likewise, the photovoltaic roofing elements can be constructed with roofing substrates having zoned functional composition, for example as described in U.S. Provisional Patent Application Ser. No. 61/089,594, which is incorporated herein by reference in its entirety.

Another aspect of the invention is a photovoltaic roofing element comprising a roofing substrate comprising a bituminous substrate and a plurality of colored roofing granules disposed thereon, the colored roofing granules having color within the color space of CIE Lab coordinates L* in the range of about 20 to about 30, a* in the range of about −5 to about 5, and b* in the range of −15 to about −5; and one or more photovoltaic elements disposed on the bituminous substrate. In this aspect of the invention, the roofing substrate need not (but can) have a solar reflectivity greater than 0.25. According to this aspect of the invention, the roofing substrate can be similar in color to the photovoltaic element, and therefore provide a more aesthetically pleasing appearance. Such roofing substrates can be constructed, for example, using colored roofing granules having a color within the color space of L* in the range of about 20 to about 30, a* in the range of about −5 to about 5, and b* in the range of −15 to about −5.

The photovoltaic roofing elements can comprise, for example, a base particle and one or more coating layers disposed thereon, as described above. In certain embodiments of the invention, the one or more coatings of the colored roofing granules are substantially free of kaolin. An algaecide such as zinc oxide or cuprous oxide can be included to prevent the formation of algae on the surface of the roofing substrate, as described, for example, in U.S. Patent Application Publication no. 2008/0241516.

Photovoltaic elements often have a somewhat metallic appearance, and sometimes have a color effect known as “flop,” depending on the viewing angle and the illumination angle. To achieve better matching of appearance between the photovoltaic elements and the roofing substrate upon which they are disposed, in certain embodiments of the invention the colored roofing granules have a multi-layer coating structure. The first coating can be, for example, the main color tone that approximates the characteristic dark blue color of a photovoltaic element. The second coating (disposed about the first) can be added to provide the metallic effect and optionally tune the color of the first coating, for example with pigments such as platelet or effect pigments. To further reduce solar heat absorption, the granules can include reflective pigments as described above and in U.S. Pat. No. 7,241,500, and U.S. Patent Application Publication no. 2005/0072110, each of which is incorporated herein by reference in its entirety.

In certain embodiments of the invention, the colored roofing granules have a metallic or light-interference effect. Such an effect can help impart a metallic visual effect to the roofing substrate, so as to better mimic the metallic effect appearance of many photovoltaic elements. For example, one or more of the coatings of the colored roofing granules can comprise a pearlescent pigment, a lamellar pigment, a light-interference pigment, a metallic pigment, an encapsulated metallic pigment, a passivated metal pigment, or metallic powder. In one embodiment of the invention, a coating having a metallic or light-interference effect surrounds a coating having a white reflective pigment as described above. This can not only increase the hiding of the base particle, but also increase the efficiency of the metallic/light-interference pigments by increasing scattering from the background.

In one embodiment of the invention, the color of the shingle can be adjusted using a blend of roofing granules. For example, the plurality of roofing granules can have a major component in the dark blue color space, with minor component in the red and/or green color space. This can help to match the color of thin film-based photovoltaic elements, as they typically have color undertones in the red/green color space. By blending dark blue colored granules with red and/or green colored granules, the person of skill in the art can better match the color appearance of thin film-based photovoltaic elements over an area of the roofing substrate. Similarly, the person of skill in the art can blend black colored roofing granules (e.g., with a solar reflectivity greater than 0.20) to change the contrast of the color blend, for example to create a variegated appearance similar to that of the photovoltaic element.

One or more of the photovoltaic roofing elements described above can be installed on a roof as part of a photovoltaic system for the generation of electric power. Accordingly, one embodiment of the invention is a roof comprising one or more photovoltaic roofing elements as described above disposed on a roof deck. The photovoltaic elements of the photovoltaic roofing elements are desirably connected to an electrical system, either in series, in parallel, or in series-parallel, as would be recognized by the skilled artisan. There can be one or more layers of material, such as underlayment, between the roof deck and the photovoltaic roofing elements of the present invention. The photovoltaic roofing elements of the present invention can be installed on top of an existing roof, in such embodiments, there would be one or more layers of standard (i.e., non-photovoltaic) roofing elements (e.g., asphalt coated shingles) between the roof deck and the photovoltaic roofing elements of the present invention. Electrical connections are desirably made using cables, connectors and methods that meet UNDERWRITERS LABORATORIES and NATIONAL ELECTRICAL CODE standards. Even when the photovoltaic roofing elements of the present invention are not installed on top of preexisting roofing materials, the roof can also include one or more standard roofing elements, for example to provide weather protection at the edges of the roof, or in any hips, valleys, and ridges of the roof.

In other embodiments of the invention, non-photovoltaically active roofing elements can be disposed on the roof along with the photovoltaic elements of the present invention. For example, the non-photovoltaically active roofing elements can have a solar reflectivity of at least about 0.25, as described above. Use of such roofing elements can help reduce the overall temperature of the roof, which can allow the photovoltaic elements to operate at higher efficiency and reduce the overall energy use of the building upon which the roof is disposed. In another embodiment of the invention, the non-photovoltaically active roofing elements have a color in the CIE color spaces described above, in order to provide aesthetic matching between the photovoltaic elements and the rest of the roof.

Another aspect of the invention is a roof comprising a plurality of photovoltaic elements disposed on a roof deck; and a plurality of roofing elements free of photovoltaic elements disposed on the roof deck, each of the roofing elements comprising a bituminous substrate and a plurality of colored roofing granules disposed thereon, the roofing substrate having color within the color space of CIE Lab coordinates L* in the range of about 20 to about 30, a* in the range of about −5 to about 5, and b* in the range of −15 to about −5. such roofing elements can be fabricated using the methods and materials described above, but omitting the photovoltaic element. In this embodiment of the invention, the non-photovoltaically active bituminous roofing elements can match the color of the photovoltaic elements. The photovoltaic elements can be, for example, configured as photovoltaic roofing elements (e.g., as described above), or can be configured in some other form (e.g., as conventional photovoltaic modules).

The invention can be further described by the following non-limiting examples.

### EXAMPLES

### Example 1

In this example, a highly reflective, white-pigmented inner coating is used as a substrate to reflect additional infrared radiation, while an outer color coating with IR-reflective pigments are used to provide desirable colors. 1 kg of white TiO₂ pigmented roofing granules with solar reflectance greater than 30% (CertainTeed Corp., Gads Hill, Mo.) are used as the base mineral particles and are colored by a second coating comprised of 100 g organic binder (Rohm and Haas Rhoplex® ELI-2000), 12 g of TZ4002 and 3 g of TZ1003 pearlescent pigments both from Global Pigments, LLC. The resultant granules are dried in a fluidized bed dryer to a free-flowing granular mass with very desirable deep, reddish gold appearance (L*=44.10, a*=20.79, b*=18.59). The cured granule sample has a high solar reflectance of 31.0%.

### Example 2

The effects of light-interference platelet pigments on solar reflectance is evaluated by a drawdown method. Samples of drawdown material are prepared by mixing 20 g of sodium silicate from Occidental Petroleum Corp. and 2 g of each of TZ5013, TZ5012, TZ4013 pearlescent pigments from Global Pigments, LLC, respectively, using a mechanical stirrer under low shear conditions. Each coating is cast from a respective sample of drawdown material using a 10 mil stainless steel drawdown bar (BYK-Gardner, Columbia, Md.) on a WB chart from Leneta Company. The resulting uniform coating is air-dried to touch and the solar reflectance is measured using a D&S Solar Reflectometer. The color is also measured using a HunterLab Colorimeter. The light-interference platelet pigments exhibit significantly higher solar reflectance over the traditional inorganic color pigments, e.g., iron-oxide red pigments (120N from Bayer Corp.; R-4098 from Elementis Corp.), ultramarine blue pigment (5007 from Whittaker), mixed metal-oxide yellow pigments (3488.times. from Bayer Corp.; 15A from Rockwood Pigments), chrome-oxide green pigments (GN from Bayer Corp.), or iron-oxide umber pigments (JC444 from Davis Colors), while creating a deep, desirable tan, gold, or purplish red colors. The results of the measurements are provided below in Table 1.

### Example 3

The effect of employing a mirrorized pigment on solar reflectance is demonstrated by using the drawdown method of Example 2. The test is repeated except that mirrorized pigments from Bead Brite Glass Products, Inc. are substituted for 20% by weight of the pearlescent pigments of Examples 3b and 3c. The results, which show further enhancement of solar reflectance, are provided in Table 1.

TABLE 1

| | | | Solar |
|---|---|---|---|
| | Pigment Type | E* | reflectivity |
| Comparative | Bayer 120N Red | 53.88 | 0.332 |
| Example 1 | | | |
| Comparative | Whittaker 5007 | 76.17 | 0.298 |
| Example 2 | Ultramarine Blue | | |
| Comparative | Elementis R4098 | 48.47 | 0.320 |
| Example 3 | Red Iron Oxide | | |
| Comparative | Davis Colors JC | 14.44 | 0.077 |
| Example 4 | 444 Umber | | |
| Comparative | Rockwood 15A | 71.93 | 0.385 |
| Example 5 | Tan | | |
| Comparative | Bayer GN Chrome | 46.46 | 0.313 |
| Example 6 | Oxide Green | | |
| Comparative | Bayer 3488x Tan | 70.54 | 0.339 |
| Example 7 | | | |
| Example 2a | Global Pigments | 91.82 | 0.653 |
| | TZ 5013 Tan | | |
| Example 2b | Global Pigments | 77.06 | 0.539 |
| | TZ 5012 Gold | | |
| Example 2c | Global Pigments | 53.66 | 0.431 |
| | TZ4013 Red | | |
| Example 3a | 65% TZ 5012 + | 81.74 | 0.560 |
| | 20% Mirrorized | | |
| | Pigment | | |
| Example 3b | 65% TZ 4013 + | 57.15 | 0.446 |
| | 20% Mirrorized | | |
| | Pigment | | |

### Example 4

A color coating is prepared by mixing 25 g of sodium silicate (grade 40 from Oxychem Corp., Dallas Tex.), 5 g of ZnO (Kadox 920 from Zinc Corp. of America), 0.5 g Portland cement, 20 g of recycled alumina grog (90A from Maryland Refractories), 6.5 g of ultramarine blue pigment (FP40 from Ferro Corp., Columbus, Ohio), 4.5 g of black pigment (10202 from Ferro Corp.), and 8 g water in a cup using a stirrer until a uniform mixture is obtained. 500 g of base rock having particle size within US #11 grading (available from CertainTeed Corp., Gads Hill, Mo.) is then blended with the coating in a 1 liter bottle by tumbling for 3 minutes to achieve uniform coverage on the base rock surface. The coated granules are dried in a fluidized bed, followed by heat treatment at elevated temperature (up to 500° C.). The above-described coating process is repeated. The final granules have a color in the CIE coordinate system as measured by a HunterLab Labscan XE calorimeter of L*=27.76, a*=0.88, b*=−11.06, and solar reflectivity=0.21 as measured according to ASTM C-1549 using a portable solar reflectometer.

### Example 5

Roofing granules having color closely matching the photovoltaic elements available from UniSolar Corp. (Auburn Hills, Mich.) are produced in this Example. The photovoltaic element (L-Cell) from UniSolar Corp. was measured for color using a HunterLab Labscan XE calorimeter at six areas, and found to have the color coordinates in Table 2, below.

TABLE 2

| | L* | a* | b* |
|---|---|---|---|
| Area 1 | 23.91 | 2.48 | −16.62 |
| Area 2 | 24.12 | 1.77 | −13.07 |
| Area 3 | 25.06 | 0.61 | −15.22 |
| Area 4 | 24.93 | 0.57 | −15.37 |
| Area 5 | 24.91 | −0.1 | −13.51 |
| Area 6 | 25.46 | −0.38 | −13.82 |

Several color coating formulations were developed and are tabulated in Table 1. Each coating was blended with 500 g of #11 grade base rock and are dried in a fluidized bed dryer prior to heat treatment at 500° C. The resulting colors and solar reflectivity are provided in Table 3. Metallic effects are introduced in this Example through the use of pearlescent pigments.

TABLE 3

| | Sample A | | | | Sample B | | | | Sample C | | | |
|---|---|---|---|---|---|---|---|---|---|---|---|---|
| | 1^{st} | | 2^{nd} | | 1^{st} | | 2^{nd} | | 1^{st} | | 2^{nd} | |
| | Coat | | Coat | | Coat | | Coat | | Coat | | Coat | |
| Base Rock (US #11 grading): | 500 | g | | | 500 | g | | | 500 | g | | |
| 1^{st} coated granules: | | | 500 | g | | | 250 | g | | | 500 | g |
| Binder (sodium silicate): | 18.7 | g | 40 | g | 50 | g | 12 | g | 50 | g | 24 | g |

| | | | | | | | | | | |
|---|---|---|---|---|---|---|---|---|---|---|
| Water: | 7 | g | 7 | g | 15 | g | 4 | g | 14.5 | 7 |

| Pigments | | | | | | |
|---|---|---|---|---|---|---|
| Black (10202 from Ferro Corp.): | 4 | g | 4.3 | g | 4.25 | g |
| Red (Rockwood): | 0.25 | g | | | | |
| Blue (FP-40 from Ferro Corp.): | 14 | g | 8.4 | g | 8.5 | g |

| | | | | |
|---|---|---|---|---|
| Pearlescent (Blue Russet, BASF): | 1.1 | g | 1 | g |

| | | | | | | |
|---|---|---|---|---|---|---|
| White (R101 from DuPont): | 10 | g | 8 | g | 10 | g |

| Pigment Extenders | | | | | | | | | |
|---|---|---|---|---|---|---|---|---|---|
| Aluminum Oxide (90A from Maryland | — | 20 | g | 35 | g | — | 40 | g | — |
| Refractories): | | | | | | | | | |

| Latent Heat Reactants | | | | | | |
|---|---|---|---|---|---|---|
| Clay: | 7.0 | g | 21 | g | 21 | g |

| | | | | | | |
|---|---|---|---|---|---|---|
| Portland Cement: | 1.62 | g | 0.486 | g | 0.81 | g |
| Aluminum Fluoride: | 5.94 | g | 1.782 | g | 2.97 | g |
| Sodium Siliconfluoride: | 0.872 | g | 0.262 | g | 0.436 | g |

| CIE Color Reading: | | | | | | |
|---|---|---|---|---|---|---|
| L* | 75.79 | 28.41 | 68.38 | 24.81 | 68.54 | 24.57 |
| a* | −0.13 | −2.57 | 0.69 | −0.99 | 0.6 | −0.97 |
| b* | 2.48 | −13.52 | 2.94 | −12.48 | 3.01 | −12.73 |
| Solar reflectivity (ASTM C-1549) | 0.44 | 0.22 | 0.36 | 0.21 | 0.36 | 0.23 |
| Alkalinity Number (ARMA Granule | 4.2 | | | | | |
| Test Method #7) | | | | | | |

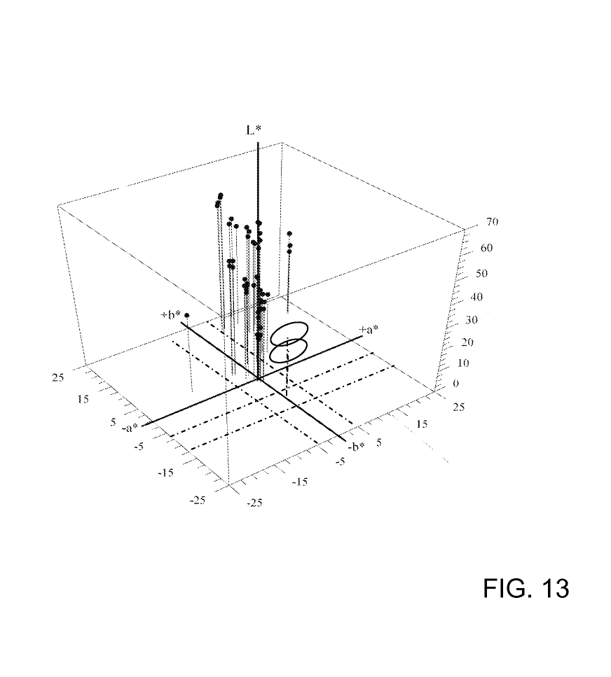

FIG. 13 is a three-dimensional plot of the color space of various commercially available conventional roofing granules. The individual points are the color coordinates for conventionally-colored, commercially available roofing granules. The area of the plot having L* in the range of about 20 to about 30, a* in the range of about −5 to about 5, and b* in the range of −15 to about −5 is in the neighborhood of the two grey oval shapes. No conventionally-colored roofing granules are found in this color space.

It will be apparent to those skilled in the art that various modifications and variations can be made to the present invention without departing from the scope of the invention. Thus, it is intended that the present invention cover the modifications and variations of this invention provided they come within the scope of the appended claims and their equivalents.

What is claimed is:

1. A photovoltaic roofing element comprising
a roofing substrate having a solar reflectivity of greater than 0.25, and
one or more photovoltaic elements affixed to the roofing substrate.

2. The photovoltaic roofing element according to claim 1, wherein the one or more photovoltaic elements is disposed on the roofing substrate.

3. The photovoltaic roofing element according to claim 1, wherein the roofing substrate has a L* less than 85.

4. The photovoltaic roofing element according to claim 3, wherein the roofing substrate has a L* less than 55.

5. The photovoltaic roofing element according to claim 3, wherein the roofing substrate has a L* less than 45.

6. The photovoltaic roofing element according to claim 1, wherein the roofing substrate has an average color falling within a color space having L* in the range of about 20 to about 30, a* in the range of about −5 to about 5, and b* in the range of −15 to about −5.

7. A photovoltaic roofing element according to claim 1, wherein the roofing substrate comprises a bituminous substrate having a granule-coated area, the granule-coated area having a plurality of solar-reflective roofing granules disposed thereon.

8. The photovoltaic roofing element according to claim 7, wherein the roofing granules have a solar reflectivity greater than about 0.3.

9. The photovoltaic roofing element according to claim 7, wherein the solar-reflective roofing granules comprise base particles coated with a first coating composition including a binder and at least one reflective white pigment; and a second coating composition disposed about the first coating composition and comprising a binder and at least one colorant selected from the group consisting of UV-stabilized dyes and granule coloring pigments.

10. The photovoltaic roofing element according to claim 7, wherein the solar-reflective roofing granules comprise base particles coated with a first coating composition comprising a binder and at least one colorant selected from the group consisting of UV-stabilized dyes and granule coloring pigments.

11. The photovoltaic roofing element according to claim 7, wherein the roofing granules have an L* less than 55.

12. The photovoltaic roofing element according to claim 7, wherein the solar-reflective roofing granules fall within a color space having L* in the range of about 20 to about 30, a* in the range of about −5 to about 5, and b* in the range of −15 to about −5.

13. The photovoltaic roofing element according to claim 7, wherein the granule-coated area of the photovoltaic roofing element has an average color falling within a color space having L* in the range of about 20 to about 30, a* in the range of about −5 to about 5, and b* in the range of −15 to about −5.

14. The photovoltaic roofing element according to claim 7, wherein the granule-coated area of the photovoltaic roofing element has a ΔE*<30 compared to the top surface of the photovoltaic element.

15. The photovoltaic roofing element according to claim 1, wherein the roofing substrate comprises a bulk material and a solar reflective coating disposed thereon.

16. The photovoltaic roofing element according to claim 15, wherein the bulk material is a polymer.

17. The photovoltaic roofing element according to claim 15, wherein the bulk material is metal, rubber, ceramic or fiber cement.

18. The photovoltaic roofing element according to claim 15, wherein the solar reflective coating comprises a first layer having a reflectivity of at least 0.25 for near-IR radiation; and a second layer disposed on the first layer, the second layer reflecting colored light but being substantially transparent to near-IR radiation.

19. A photovoltaic roofing element comprising
a roofing substrate comprising a bituminous substrate and a plurality of colored roofing granules disposed thereon, the roofing substrate having color within the color space of CIE Lab coordinates L* in the range of about 20 to about 30, a* in the range of about −5 to about 5, and b* in the range of −15 to about −5; and
one or more photovoltaic elements affixed to the bituminous substrate.

20. The photovoltaic roofing element according to claim 19, wherein the colored roofing granules comprise a base particle and one or more coating layers disposed thereon.

21. The photovoltaic roofing element according to claim 20, wherein the one or more coatings of the colored roofing granules are substantially free of kaolin.

22. The photovoltaic roofing element according to claim 19, wherein the colored roofing granules have a metallic or light-interference effect.

23. The photovoltaic roofing element according to claim 22, wherein one or more of the coatings of the colored roofing granules comprise a pearlescent pigment, a lamellar pigment, a light-interference pigment, a metallic pigment, an encapsulated metallic pigment, a passivated metal pigment, or metallic powder.

24. The photovoltaic roofing element according to claim 22, wherein the one or more coating layers comprise a reflective white layer; and a metallic or light-interference layer surrounding the reflective white layer.

25. The photovoltaic roofing element according to claim 19, further comprising a plurality of colored roofing granules having a color in the red-green color space.

26. The photovoltaic roofing element according to claim 19, further comprising a plurality of black roofing granules having a solar reflectivity greater than about 0.2.

27. The photovoltaic roofing element according to claim 19, wherein the roofing substrate has a solar reflectivity greater than about 0.2.

28. A roof comprising a plurality of photovoltaic roofing elements according to claim 1 disposed on a roof deck.

29. A roof comprising
a plurality of photovoltaic elements disposed on a roof deck; and
a plurality of roofing elements free of photovoltaic elements disposed on the roof deck, each of the roofing elements comprising a bituminous substrate and a plurality of colored roofing granules disposed thereon, the roofing substrate having color within the color space of CIE Lab coordinates L* in the range of about 20 to about 30, a* in the range of about −5 to about 5, and b* in the range of −15 to about −5.
